(19) United States
(12) Patent Application Publication
(10) Pub. No.: US 2007/0193775 A1
(43) Pub. Date: Aug. 23, 2007

(54) Impedance matching via structure for high-speed printed circuit boards and method of determining same

(75) Inventors: Houfei Chen, Boise, ID (US); Shiyou Zhao, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/357,544

(22) Filed: Feb. 17, 2006

(51) Int. Cl. H05K 1/11; H01R 12/04

(52) U.S. Cl. 174/262

(57) ABSTRACT

An impedance matching conductive via structure that is effectively constructed by selecting an outer conductor and an inner conductor diameter through analytical calculation or numerical simulation, such that impedance of the conductive via structure is matched to the impedance of the conductive signal traces of a printed circuit board. The conductive via structure comprises a conductive barrel that either connects to multiple ground planes or to multiple powers planes and serves as the outer conductor for a coaxial structure that provides a current return path and a matched impedance path of via transition, thus improving the signal transition and reducing signal reflection due to via discontinuity. Moreover, the conductive barrel of the conductive via structure also reduces radiation loss through a parallel plane structure and suppresses coupling between neighboring vias as the energy escaping through the conductive barrel and radiating to other vias is minimized.

### FIELD OF THE INVENTION

This invention relates to a semiconductor interconnect structure and the design method thereof and, more particularly, to a printed circuit board (PCB) interconnect structure and the design method thereof.

### BACKGROUND OF THE INVENTION

For high-speed digital PCB design, through-hole vias (openings) are used extensively to connect signal traces on different layers. Due to the intrinsic geometrical difference between via and its connected traces, there exists impedance mismatch at a via transition. As circuit switching speed dramatically increases into the multi-Gbps range, and the physical size of the circuit continues to shrink, this via impedance mismatch poses a serious problem.

In a multi-layer PCB structure, vias are used extensively to facilitate routing of signal traces from one signal layer to another. As mentioned, due to the intrinsic geometrical difference between a via and signal traces (typically, one is in the form of a cylindrical hole with no reference planes, while the other is in the form of a planar structure with nearby ground/power planes as reference), there exists impedance mismatch during a via transition from the signal layer. This impedance mismatch gets worse as signal transition speeds dramatically increase into the multi-Gbps range. For example, for a 3.2 Gbps signal. The signal integrity analysis requires considering up to the 3^{rd} harmonic, which corresponds to 9.6 GHz for this case. As the frequency increases, the electrical length of a via impedance mismatching section becomes longer in relation to the signal and poses a more serious problem than at a low frequency range. Also, as the physical size of the circuit becomes more compact the via diameter shrinks as well, and this shrinkage in size increases the inductance of the via structure, which, in turn, increases the impedance mismatch of the via structure. Such impedance mismatch degrades signal integrity and consumes operating voltage margin.

FIG. 1 and FIG. 2 show the cross sectional view and side view, respectively of a conventional via structure. In both FIGS. 1 and 2, Printed Circuit Board (PCB) assembly 10 is depicted where a top conductive signal interconnect trace 11 routes along the top of dielectric material 18 and then switches to a bottom conductive signal interconnect trace 13 along the bottom of dielectric material 18 through a conductive via structure 12 by way of antipad 20. In this typical PCB arrangement as depicted in FIG. 1 and 2, both conductive planes 14 and 15 are ground planes (GND) or power planes (VDD) (other possible planes are omitted for clarity). The top conductive signal interconnect trace 11 and bottom conductive signal interconnect trace 13 both reference electrically to the same family of conductive planes (GND or VDD), which is intended to preserve return path continuity (a commonly encountered situation on a PCB assembly). With this arrangement, although conductive via structure 12 does not induce any return path discontinuity problem due to referencing to the same plane family (GND or VDD), the conductive via structure 12 does exhibit impedance mismatch between the conductive signal interconnect trace 13 and the conductive via cylinder 12, which degrades signal integrity especially at high frequency.

A simulation of circuit structures depicted in FIG. 1 and FIG. 2 is illustrated in FIG. 5 and FIG. 6. The PCB assembly 10 stack in FIG. 1 has four conductive layers, with the top and bottom conductive layers (11 and 13) as signal carrying conductive interconnect layers and containing VDD patches 19; the second and third layers (14 and 15) as two conductive ground planes. The dielectric material 18 between top GND plane 14 and top conductive signal interconnect trace 11 possesses a dielectric constant of approximately 4.4 and a dielectric thickness of approximately 5.5 mils (1 mil=1 milli-inch) which includes approximately 1.8 mils thickness of conductive signal interconnect trace 11. This is the same case for the dielectric material between bottom GND plane 15 and bottom conductive signal interconnect 13.

The dimensions of PCB assembly 10 are 2 inches by 6 inches with a core thickness of 54 mils between the two ground planes 14 and 15. The dimensions of the via structure are: via cylinder 12 is 8 mils in diameter, via pad (or via top pad 16 and via bottom pad 17) 18 mils in diameter and via antipad 24 mils in diameter. The conductive signal interconnect traces (top and bottom conductive signal interconnect traces 11 and 13) are microstrip with trace width 5 mils, trace thickness 1.8 mils and trace height 3.7 mils. Each conductive signal interconnect trace 11 and 13 exhibits a characteristic impedance of around 50 Ohms. The scattering parameter (S-parameter), a standard metric for signal integrity, is used to gauge the magnitude of signal transmission through the via structure, as well as the signal reflection due to the via impedance discontinuity.

The simulation is setup and run in HFSS, which is a full-wave 3-D EM solver from Ansoft Corporation, to extract the S-parameter from DC to 10 GHz signal. The curve labeled “normal via” in FIG. 5 shows the transmission coefficient (S12) of the signal. As can be seen at high frequencies, as much as −3 dB insertion loss can occur. Such signal degradation inevitably lowers the voltage margin for high-speed applications. The curve labeled “normal via” in FIG. 6 shows the reflection coefficient (S11) of the signal, which reaches −15 dB to approximately −12 dB at high frequencies. This corresponds to a signal reflection amplitude of 17% to approximately 25% at high frequencies. Such high reflection increases the Inter-Symbol Interference (ISI) for high speed application. These simulations demonstrate how an impedance mismatch during a normal via transition between the signal layers degrades signal integrity and consumes operating voltage margin.

The present invention describes a new via structure and a method to form same that addresses the impedance mismatch at a via transition as discussed above.

### SUMMARY OF THE INVENTION

An exemplary implementation of the present invention includes an impedance matching conductive via structure that is effectively constructed by selecting an outer conductor and an inner conductor (a via cylinder) diameter through analytical calculation or numerical simulation, such that impedance of the conductive via structure is matched to the impedance of the conductive signal traces of a printed circuit board. The conductive via structure comprises a conductive barrel that either connects to multiple ground planes or to multiple power planes and serves as the outer conductor for a coaxial structure. The conductive via structure also provides a current return path and a matched impedance path of via transition, thus greatly improving the signal transition and reducing signal reflection due to via discontinuity. Moreover, the conductive barrel of the conductive via structure also reduces radiation loss through a parallel plane structure and suppresses coupling between neighboring vias as energy escaping through the conductive barrel and radiating to other vias is minimized.

### BRIEF DESCRIPTION OF THE DRAWING

FIG. 1 and FIG. 2 show a cross sectional view and side view of a conventional via structure for a printed circuit board.

FIG. 3 and FIG. 4 depict an embodiment of the present invention that show a cross sectional view and side view of a via structure for a printed circuit board.

FIG. 5 is a top view of a typical printed circuit board (PCB) showing VDD patches and signal traces, trace pads, antipads and vias.

FIG. 6 depicts a PCB after an antipad opening is drilled into a core material and the core material and the antipad opening is plated with conductive material.

FIG. 7 depicts a PCB after the plated antipad opening and the plated core material is coated with dielectric material.

FIG. 8 depicts a PCB after a via cylinder structure is formed along with via pads and signal traces.

FIG. 9 shows a via transition electrical simulation of the conventional via structure, depicted in FIG. 1 and FIG. 2, compared to the via structure of the present invention depicted in FIG. 3 and FIG. 4.

FIG. 10 shows a via reflection electrical simulation of the common via structure, depicted in FIG. 1 and FIG. 2, compared to the via structure of the present invention depicted in FIG. 3 and FIG. 4.

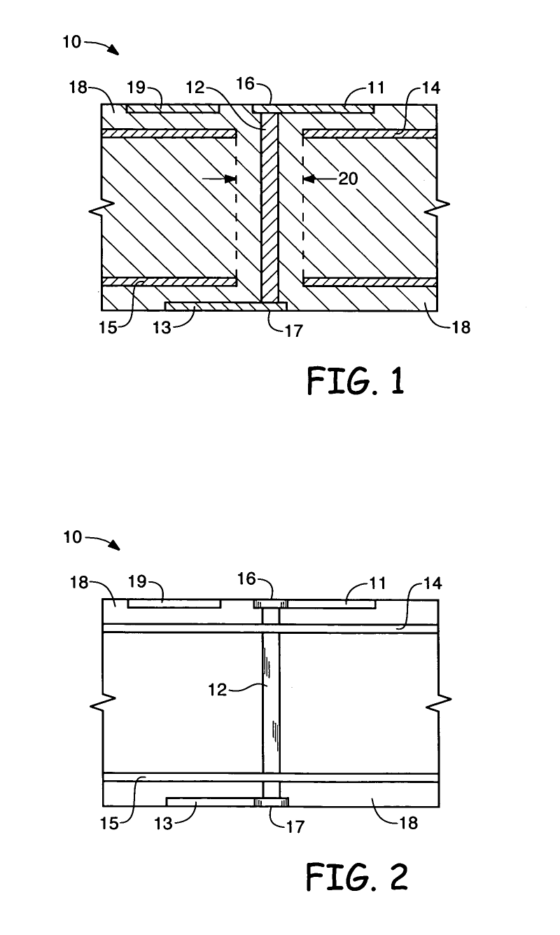

### DETAILED DESCRIPTION OF THE INVENTION

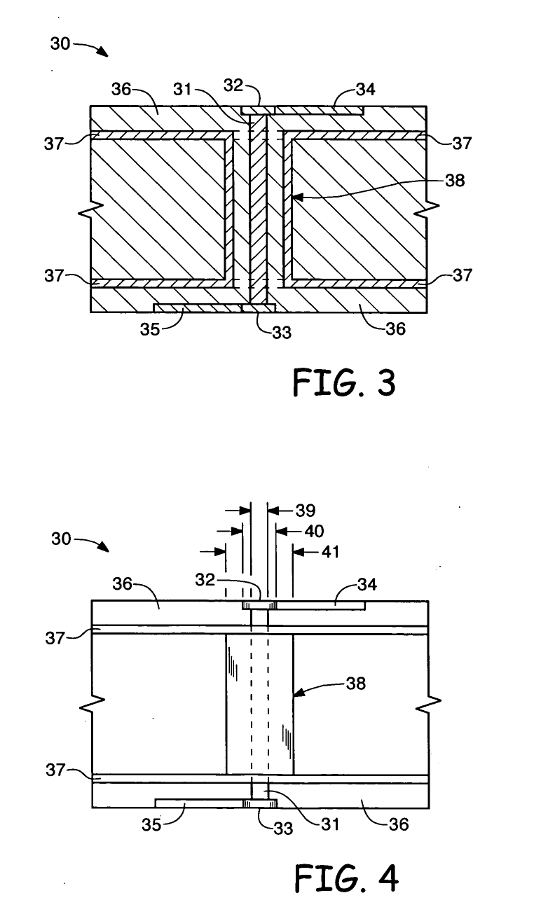

An exemplary implementation of the present invention is directed to a printed circuit board via structure and a design process for forming same, as depicted in FIGS. 3 and 4.

Referring to FIG. 3, the cross sectional view of PCB member 30 shows a conductive cylindrical barrel 38 extending around and in electrical isolation from via cylinder 31 which forms an impedance matching PCB via structure. Top conductive via pad 32 and bottom conductive via pad 33 connect to the top and bottom ends of via cylinder 31, respectively. Top and bottom conductive signal interconnect traces 34 and 35 connect to top conductive via pad 32 and bottom conductive via pad 33, respectively. The conductive cylindrical barrel 38 is added around the via cylinder structure 31.

Referring to both in FIG. 3 and FIG. 4, conductive barrel 38 connects to both ground planes 37 (or to other power planes depending on the PCB design) and serves as the outer conductor which forms a coaxial structure including via cylinder 31 and conductive barrel 38, separated by dielectric material 36. The pad diameter 40 of top conductive via pad 32 and bottom conductive via pad 33 only needs to be of sufficient size such that it is larger than the via cylinder diameter 39 so that substantial conductive connection is made between the via cylinder and the conductive signal interconnect traces 34 and 35.

Referring to FIG. 4, by carefully selecting the outer conductor diameter (antipad diameter 41) and inner conductor diameter (via cylinder diameter 39) through analytical calculation or numerical simulation of a via structure, such as the via structure depicted in FIG. 4 that comprises conductive via cylinder 31, top and bottom conductive via pads 32 and 33 and conductive barrel 38 separated from via cylinder 31 by dielectric material 36 is designed to have an impedance which matches to the impedance of the conductive signal interconnect traces 34 and 35.

For example, the impedance (Z) of the matched impedance via structure is calculated as:
Z=(138/√Er) log(D/d)
where: Z=the impedance of the matching via structure

D=diameter of outer conductive barrel, i.e. conductive cylindrical barrel 38

d=diameter of the inner conductive cylinder, i.e., conductive via cylinder 31

Er=dielectric constant of the material separating the outer conductive barrel and inner conductive cylinder, i.e., conductive cylindrical barrel 38 and conductive via cylinder 31.

First, D or d is determined based on manufacturing constraints. For example: set d=4 mils, then according to the formula, with Er=4.4, to achieve impedance of 50 Ohms, then D=24 mils. Thus:
Z=(138/√1.0) log(24 mils/4 mils)=51.19 Ohms.
However, if the dielectric material inside the barrel is removed, the via diameter can be further relaxed to d=10 mils, then:
Z=(138/√4.4) log(24 mil/10 mil)=52.47 Ohms.
Thus, using simulation software, diameter parameters “D” and “d” may be set as optimization variables with constraint to achieve 50 Ohms impedance of the present example above, but more importantly to achieve the impedance of the signal trace.

The via structure of the present invention provides a current return path and a matched impedance path of via transition, thus greatly improving the signal transition and reducing signal reflection due to via discontinuity. Moreover, the conductive barrel 38, shown in FIGS. 3 and 4, also serves the purpose of reducing radiation loss through a parallel plane structure and suppressing coupling between neighboring conductive vias as there is little energy that will escape through the conductive barrel and radiate to other vias.

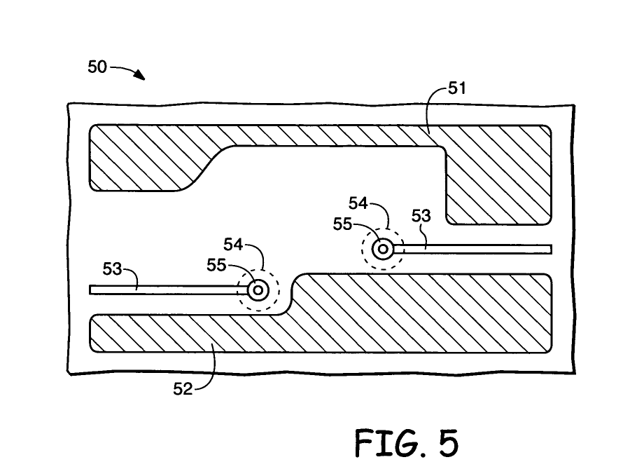

FIG. 5 is a top view of a typical printed circuit board (PCB) 50 showing a top layer of isolation 51 formed over the PCB 50 and having conductive patches 52, such as VDD patches, signal traces 53, antipads 54, vias 55 and trace pads 56 formed thereon by fabrication techniques know to one skilled in the art.

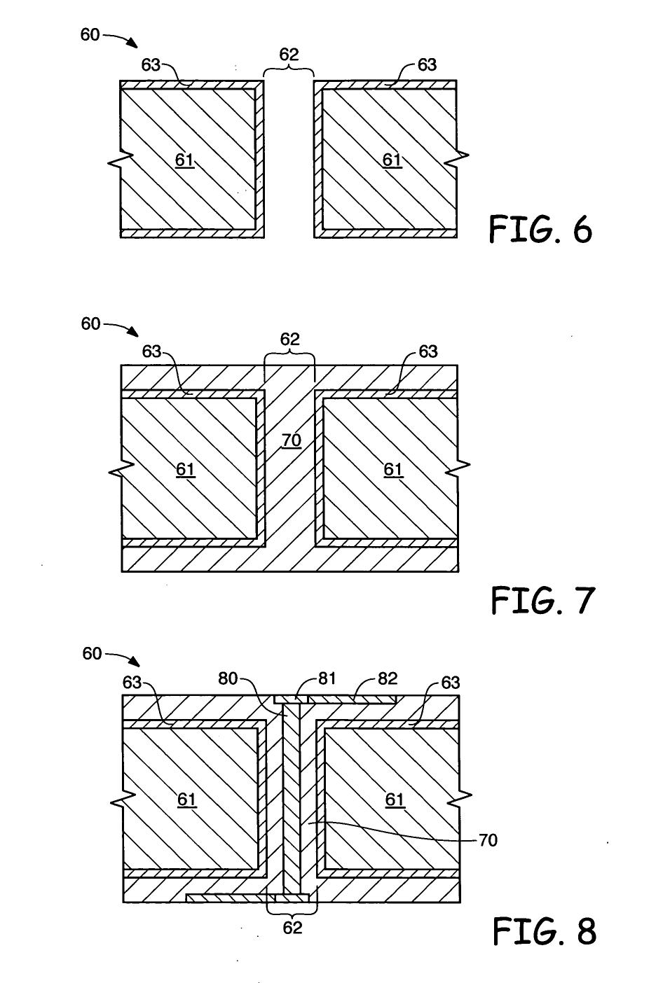

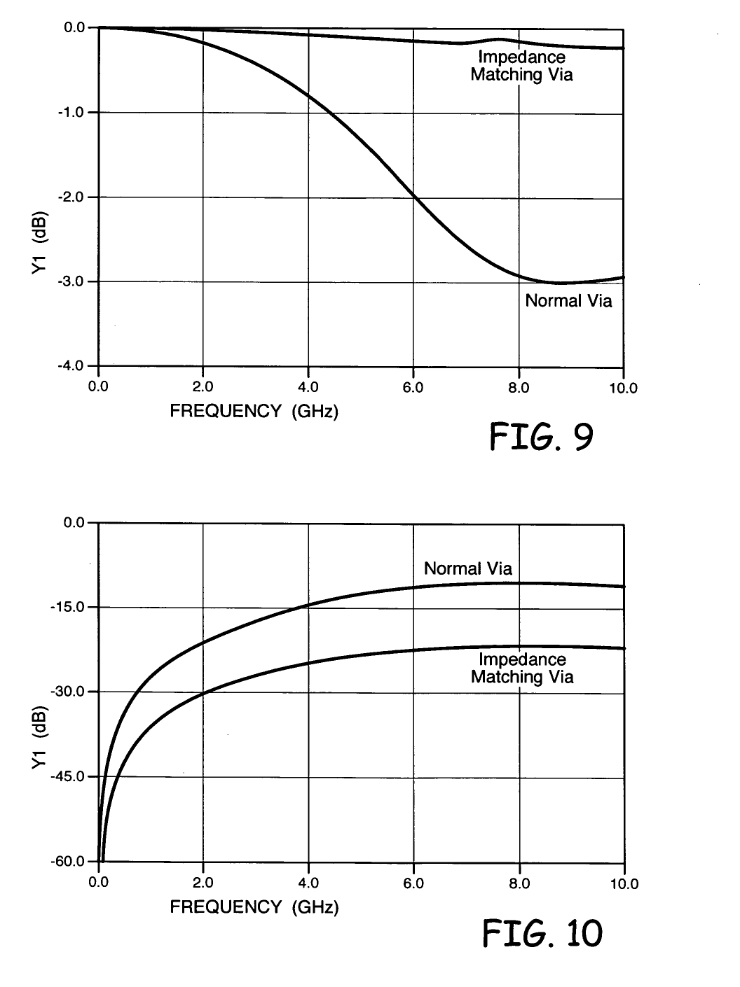

The layout of the typical PCB of FIG. 5 is modified by adding the impedance matching via structure of the present invention as depicted in FIGS. 6-8 by using fabrication techniques know to one skilled in the art.

Referring now to FIG. 6, an antipad opening 62 is drilled into a core material 61 of a PCB 60. The core material 61 and the antipad opening 62 is plated with conductive material 63, such as copper. The plated antipad opening 62 becomes the outer conductive barrel of the present invention.

Referring now to FIG. 7, the plated antipad opening 62 is filled with dielectric material 70 and the plated core material 61 is coated with dielectric material 71.

Referring now to FIG. 8, a via cylinder structure 80 is formed inside plated antipad opening 62. Via pads 81 are formed thereon and signal traces 82 formed to connect to the via pads. The outer conductive barrel and the via cylinder structure residing therein form the impedance matching via structure of the invention.

A simulation of circuit structures depicted in FIG. 3 and FIG. 4 is illustrated in FIG. 5 and FIG. 6. To achieve an impedance of around 50 Ohms in order to match the signal trace characteristic impedance, the via diameter (d) is set at 4 mils and the antipad diameter is set at 24 mils which is also the diameter (D) of the conductive cylindrical barrel 38. In FIG. 5 the curve labeled “impedance matching via” clearly has a much better signal transmission compared to a traditional via across the entire frequency range. The matched impedance via achieves an insertion loss of merely −0.2 dB compared to −3 dB of the traditional via. Translated to amplitude, this means a signal transmission amplitude of 97.7% for the proposed via structure versus 70.7% for the traditional via.

Shown in FIG. 6, when evaluating signal reflection, the curve labeled “impedance matching via structure” also gives a return loss that is significantly below that of the traditional via across the entire frequency range. The maximum return loss of the proposed via structure is only −22 dB, which is a signal reflection of 7.9% compared to 17.8% to approximately 25% of the traditional via. The loss calculations show the impedance matched via structure has an energy loss of 3.9% ((1−0.977²−0.079²)=0.039 or 3.9%), while the traditional via has an energy loss of 43.8% ((1−0.707²−0.25²)=0.438 or 43.8%) for the high frequency components of signal.

In summary, this impedance-matched via structure may find applications in high-speed (high performance) signaling PCB boards, especially the multi-Gbps range where signals have little room for signal integrity degradation because of a tighter timing budget and a lower noise margin. More importantly, in high-speed signaling, signals have a much broader bandwidth of frequency, thus ensuring maximum signal transmission and minimum signal reflection across the entire frequency range are critical for error-free communication. The impedance matching via structure of the present invention effectively addresses these issues at all frequencies by providing a matched impedance path as well as a closer return path for via transition. Moreover, energy loss due to the parallel plane structure, via coupling and radiating energy is also significantly suppressed.

It is to be understood that although the present invention has been described with reference to at least one preferred embodiment, various modifications, known to those of ordinary skill in the art may be made to the process steps presented herein without departing from the invention as recited in the several claims appended hereto.

What is claimed is:

1. A printed circuit board interconnect structure comprising:
an impedance matching via structure comprising an inner conductor and a surrounding outer conductor of selected respective diameters that exhibits an impedance matched to an impedance of attached signal traces of a printed circuit board.

2. The printed circuit board interconnect structure of claim 1, wherein the impedance matching via structure comprises a conductive barrel that connects to a plurality of ground planes or power planes.

3. The printed circuit board interconnect structure of claim 2, wherein the conductive barrel effectively reduces radiation loss through a parallel plane structure and suppresses coupling between impedance matching via structures.

4. The printed circuit board interconnect structure of claim 1, wherein the impedance matching via structure serves as an outer conductor for a coaxial structure.

5. The printed circuit board interconnect structure of claim 1, wherein the impedance matching via structure provides a current return path and a matched impedance path during signal via transition.

6. A method for determining the physical characteristics of a printed circuit board interconnect structure comprising:
designing an impedance matching via structure by selecting an outer conductive barrel diameter and an inner conductor cylinder diameter of the impedance matching via structure through analytical calculation or numerical simulation, such that an impedance matched to an impedance of an associated signal trace of the printed circuit board is achieved by using the formula:
Z=(138/√Er) log(D/d)
where:
Z=the impedance of the matching via structure
D=diameter of outer conductive barrel
d=diameter of the inner conductive cylinder
Er=dielectric constant of the material separating the outer conductive barrel and inner conductive cylinder.

7. The method of claim 6, further comprising:
determining D or d based on manufacturing constraints of a via interconnect.

8. The method of claim 6, further comprising:
setting D and d as optimization variables to achieve the impedance of the associated signal trace of the printed circuit board interconnect structure.

9. The method of claim 6, further comprising adding a conductive barrel that connects to either a plurality of ground planes or to a plurality of power planes and serves as the outer conductor for a coaxial structure.

10. The method of claim 6, wherein the impedance matching via structure provides a current return path and a matched impedance path during signal via transition.

11. The method of claim 6, wherein the conductive barrel reduces radiation loss through a parallel plane structure and suppresses coupling between impedance matching via structures.
